(19) United States
(12) Patent Application Publication
(10) Pub. No.: US 2024/0364072 A1
(43) Pub. Date: Oct. 31, 2024

(54) ILLUMINATION DEVICE

(71) Applicant: OSRAM OPTO SEMICONDUCTORS GMBH, Regensburg (DE)

(72) Inventors: Hubert HALBRITTER, Dietfurt-Toeging (DE); Bruno JENTZSCH, Regensburg (DE)

(73) Assignee: ams-OSRAM International GmbH, Regensburg (DE)

(21) Appl. No.: 18/565,879

(22) PCT Filed: May 31, 2022
(86) PCT No.: PCT/EP2022/064802

§ 371 Date: Nov. 30, 2023

(30) Foreign Application Priority Data
Jun. 1, 2021 (DE) 10 2021 114 225.3

(51) Int. Cl. H01S 5/00; F21V 9/32; F21Y 113/00; F21Y 115/30; H01S 5/02255; H01S 5/024; H01S 5/42

(52) U.S. Cl. CPC H01S 5/0087; F21V 9/32; H01S 5/02255; H01S 5/02476; H01S 5/42; F21Y 2113/00; F21Y 2115/30

(57) ABSTRACT

The invention relates to an illumination device having a housing with a light-exit region and an assembly element arranged below the light-exit region. A conversion element is arranged on the assembly element and designed to convert pump light into emission light in a surface region of the conversion element and to emit said emission light via the surface region. Two surface-emitting laser apparatuses for producing the pump light are arranged opposite one another on the assembly region and are arranged laterally offset to the light-exit region and arranged at a distance from the conversion element and at a distance therefrom. A reflector element connected to the housing is arranged above laser apparatuses and designed to reflect the pump light emitted by the laser apparatuses onto the surface region. The assembly element serves the purpose of heat dissipation for the heat produced and, at the same time, substantial thermal decoupling from the conversion element.

### CROSS-REFERENCE TO RELATED APPLICATIONS

The present invention is a national stage entry from International Application No. PCT/EP2022/064802, filed on May 2022, 31, published as International Publication No. WO 2022/253851 A1 on Dec. 8, 2022, and claims the priority of the German first application DE 10 2021 114 225.3 filed Jun. 1, 2021, the disclosures of all of which are hereby incorporated by reference in their entireties.

### FIELD

The invention relates to a lighting device.

### BACKGROUND

Some applications, for example in the automotive sector, require very high luminous intensity for lighting device. For the generation of white light, two different variants are used. In the first variant, light of different colors is generated by light-emitting diodes or lasers and mixed directly. For example, red, green and blue lasers can be used for this purpose, whose mixed light produces white light.

Alternatively, white light can also be produced by means of a blue pump light and subsequent conversion with a yellow dye. Such conversion elements are also referred to in simplified terms as phosphors. One disadvantage of such applications, however, is thermal degradation. If a large thermal load is applied, the efficiency of the conversion element decreases and color shifts can occur. In addition, the conversion dye ages much faster and the service life of the components is reduced as a result.

Accordingly, there is a need to specify lighting devices with very high luminosities, where the above disadvantages are reduced.

### SUMMARY OF THE INVENTION

The inventors have recognized that thermal decoupling of the laser devices and the conversion element enables a compact design and increases the lifetime of such lighting devices. They take advantage of several aspects that together achieve the desired goal.

In one aspect, a lighting device comprises a housing having a light emitting region and a mounting element disposed below the light emitting region. A conversion element is disposed on and thermally connected to the mounting element. The conversion element is now designed to convert pump light of one wavelength, which falls on the conversion element in a surface region, into a radiation light with a second wavelength and to radiate it over the surface region, which lies below the light exit region (16). Furthermore, a first and a second surface-emitting laser device for generating the pump light are provided, which are arranged on the mounting area laterally offset from the light exit area. The first laser device is thereby thermally coupled along a first side of the conversion element and spaced therefrom on the mounting element. The second laser device is spaced along a second side of the conversion element opposite the first side and is also thermally attached to the mounting element.

Finally, the lighting device comprises a reflector element connected to the housing, which is arranged above the first and second laser devices and is designed to reflect the pump light emitted by the laser devices onto the surface area. The lighting device is thus designed to generate a mixed light that is formed on the one hand from a pump light component and on the other hand from a converted light component.

The degree of conversion and thus the color of the mixed light can be adjusted by the concentration of converter particles in the conversion element, the shape or the design.

Finally, according to the proposed principle, the mounting element is designed for heat dissipation of heat generated during operation of the first and second laser devices while at the same time providing extensive thermal decoupling from the conversion element. This can be achieved on the one hand by a suitable size of the mounting element, but also by the mentioned spacing of the laser devices from the conversion element. Due to the thermal decoupling, the light output on the conversion element can be increased without its conversion efficiency being significantly affected by waste heat from the laser devices.

Another aspect concerns symmetry, since uniform illumination of the conversion element reduces temperature gradients and thus increases service life. In addition, a more uniform distribution of the mixed light is achieved over the entire emission space. To this end, in some aspects, the lighting device comprises third and fourth laser devices arranged opposite each other and spaced apart from the conversion element, such that the laser devices optionally lie along or on the sides of a notional rectangle around the conversion element.

In one aspect, the first and/or second laser devices comprise at least one HCSEL or a VCSEL. Similarly, the third and fourth laser devices may comprise an HCSEL or a VCSEL as surface emitting lasers. On the one hand, such lasers are characterized by a compact design and offer a very high luminescence with simultaneously low waste heat. As a result, a very high illuminance can be achieved by the mixed light. In one aspect, a surface emitting region of the HCSEL or the VCSEL is parallel to the surface region of the conversion element. the pump light is thus emitted substantially perpendicular to the surface and directed by the reflector element onto the surface region of the conversion element.

In other aspects, the at least one HCSEL or VCSEL each comprises light-shaping optics integrated into the surface emitting region such that emission of the pump light occurs at an angle tilted from perpendicular, particularly toward the conversion element. Thus, in some aspects, a steeper angle of incidence on the surface emitting region of the conversion element can be achieved. Again, in other aspects, the at least one HCSEL or VCSEL comprises at least one light-shaping optic disposed on the respective surface emitting region such that radiation of the pump light occurs at an angle tilted with respect to the perpendicular, particularly toward the conversion element. It should be mentioned here that the optics explained here form a part of the laser device and especially of the HCSEL or the VCSEL.

In some aspects, as noted, the laser device is formed with one or more HCSELs. This comprises a laser resonator that is substantially perpendicular to the side of the conversion element adjacent to the laser device. The surface emitting region of the HCSEL, also referred to as the outcoupling region lies adjacent to the conversion element. Thus, in some aspects, a highly reflective region of the laser cavity faces away from the conversion element.

In other aspects, the laser resonator substantially perpendicular to the side of the conversion element adjacent to the laser device comprises a decoupling region facing away from the conversion element. In some aspects, a laser cavity of at least one HCSEL of a laser device extends at least partially below the conversion element, wherein the surface emitting region of the laser device is adjacent to the conversion element.

In some aspects, the surface emitting region of the surface emitting laser and in particular the HCSEL comprises an etched facet in a trench, in particular with an angle of 40° to 50°.

Another aspect concerns the housing and the reflector element. For example, the housing may be at least partially filled with a transparent material. In this context, the reflector element may be arranged on the housing or may also be integrated in the material of the housing.

In another aspect, a reflective surface of the reflector element is aligned parallel to the surface area of the conversion element. In this aspect, the aforementioned optics are provided in the laser device such that light is incident on the reflector surface at an angle not equal to 90°. In some aspects, the reflector element is formed as a ring with an inner recess forming the light emitting area. This may also provide a more uniform impression by a user looking at the housing from the outside. A ring can also be easily aligned and integrated into or placed on the transparent material of the housing.

In another aspect, the reflector element is configured as a truncated cone. As a result, the reflective surface of the reflector element is generally inclined with respect to the surface region of the conversion element, this can in some embodiments improve reflection so that light strikes the surface region of the conversion element at a steeper or shallower angle.

In some examples, the surface is coated with or made of a metal, in particular silver or aluminum. In a very simple case, the reflector element can also simply be a metallic thin film deposited on or integrated into the housing.

In some aspects, a special light extraction structure is provided for further light shaping. This may comprise a light guiding or light shaping optic, but may also simply serve to better couple light out of the material of the housing. The optics or also the light outcoupling structure can be integrated in the light emitting area or arranged on it. The latter allows some flexibility depending on the desired application.

In another aspect, the lighting device relates to light guiding or shaping within the housing of the lighting device. In one aspect, the conversion element comprises a member surrounding the surface region of the conversion element, such that the member extends over the surface region toward the light emitting region. This surrounding element can redirect or reflect stray light onto the light emitting region. To this end, in some aspects, it is made with TiO₂ or another white or reflective material. In other aspects, the surrounding element may also be formed with a metal, in which case there may be additional thermal coupling to the housing or mounting element. This further reduces a possible thermal load and enables good heat dissipation.

In some aspects, to reduce possible stray light, the surrounding element is provided with recesses as a ring. These are at positions for the pump light to pass through the surrounding element. In another aspect, the surrounding element has a reflective surface. Alternatively or additionally, it may be inclined so that the surface adjoining the surface region forms a reflective wall that reflects light emitted from the conversion element onto the light emitting region. Likewise, in some aspects, it is possible to have an inwardly facing outer surface of the conversion element be reflective. As a result, either pump light but also converted light is reflected back. In this context, it is useful to provide at least the bottom of the conversion element, i.e. the contact surface on the mounting element, with a reflective layer.

### BRIEF DESCRIPTION OF THE DRAWINGS

Further aspects and embodiments according to the proposed principle will become apparent with reference to the various embodiments and examples described in detail in connection with the accompanying drawings.

FIG. 1 shows a first embodiment according to the proposed principle in plan view;

FIG. 2 shows a side view of the design shown in FIG. 1;

FIG. 3 shows a second embodiment of a lighting device with some aspects of the proposed principle;

FIG. 4 illustrates a further design of a lighting device with VCSEL matrices;

FIG. 5 shows an embodiment of a lighting device with some aspects of the proposed principle;

FIG. 6 shows a side view of a design form of a lighting device;

FIG. 7 shows the side view of the embodiment of FIG. 5 with some aspects of the proposed principle;

FIG. 8 shows the side view of the design form of FIG. 3 or on the FIG. 4 modified view;

FIG. 9 shows a first embodiment of an HCSEL as applicable in a lighting device according to the proposed principle;

FIG. 10 shows a second embodiment of an HCSEL as applicable in a lighting device according to the proposed principle;

FIG. 11 shows a third embodiment of an HCSEL as applicable in a lighting device according to the proposed principle;

FIG. 12 shows embodiments of a VCSEL as it can be used in a lighting device according to the proposed principle;

FIG. 13 presents a top view of another embodiment of a lighting device with some aspects of the proposed principle;

FIG. 14 shows a side view of the lighting device of FIG. 13;

FIG. 15 is a top view of another embodiment of a lighting device with some aspects of the proposed principle;

FIG. 16 shows a side view of the lighting device of FIG. 15.

### DETAILED DESCRIPTION

The following embodiments and examples show various aspects and their combinations according to the proposed principle. The embodiments and examples are not always to scale. Likewise, various elements may be shown enlarged or reduced in size to highlight individual aspects. It will be understood that the individual aspects and features of the embodiments and examples shown in the figures may be readily combined without affecting the principle of the invention. Some aspects comprise a regular structure or shape. It should be noted that minor deviations from the ideal shape may occur in practice, but without contradicting the inventive idea.

Figure one shows a first embodiment of a lighting arrangement of the proposed principle in a top view. Figure two is the corresponding representation in a side view. The lighting device is integrated in a housing 19, which can be rectangular or square, for example. Different shapes with regard to the size and the shape of the lighting device are possible. In addition to the housing 19, the lighting device also comprises a mounting element 14 which performs several functions. On the one hand, the mounting element 14 serves to fix the various further elements of the lighting device and, on the other hand, it fulfills the task of efficiently dissipating heat generated mainly by the laser devices during operation of the lighting device and, in particular, away from the conversion element.

A total of four non-shaped surface emitting laser devices 10a, 10b, 10c and 10d are arranged on the mounting element 14. The surface emitting laser devices are designed as HCSEL (horizontal cavity surface emitting lasers). In this embodiment, all of the laser devices 10a show a total of two surface emitting regions 101 arranged at the opposite ends of the laser devices 10a to 10d. The 4 laser devices 10a to 10d are arranged on a virtual and fictitious line of a square along the respective sides. A conversion element 12 is now applied to the mounting element 14 in the space formed by the laser device. The conversion element 12 comprises a border which is objected to by the respective laser devices. The spacing is thereby selected such that in an operation of the laser devices a thermal coupling between the laser devices and the conversion element is excluded. A thermal connection takes place, if at all, only via the mounting element 14.

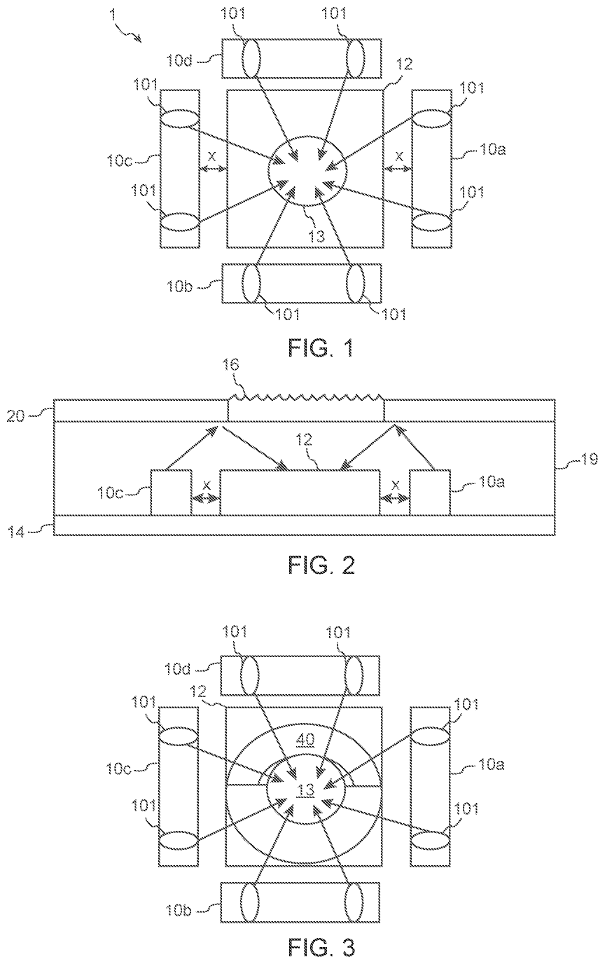

A reflector element 20 is mounted above the housing 19 as shown in the side view of FIG. 2. This is not shown in the top view of FIG. 1 for reasons of clarity. The reflector element 20 extends from the edge of the housing to approximately the height of the conversion device 12. A decoupling element 16 is arranged between the reflector element, which is transparent to the light emitted by the conversion element. In one operation, the laser devices 10a to 10d generate light of a pump wavelength that is also referred to hereinafter as pump light and radiate this via their surface emitting areas 101 in the direction of the conversion element 12. In this case, the radiated direction occurs at an inclined angle, i.e. not along the perpendicular to the respective surface emitting area for this purpose, optics or other elements are provided, the following in more detail.

The pump light emitted by the laser devices falls on the reflector element 20 and is directed by it towards a surface area 13 of the conversion element 12. Within this surface area of the conversion element, a conversion of the pump light into light of a second wavelength takes place. The concentration of the converter particles within the area 13 and also the conversion element 12 is selected in such a way that, together with the pump light, a conversion into light of a yellow wavelength takes place, so that a white mixed color im produced. The surface area shown in FIG. 1 is substantially circular due to the elliptical cone of pump light incident on the surface area 13.

Due to the distance of the laser devices from the conversion element 12, a thermal decoupling between the elements is ensured the mounting element, on which both the laser devices 10a to 10d and the conversion element 12 are mounted, serves in particular to dissipate the heat generated by the operation of the laser devices or the light convention. In this regard, the mounting block 14 is configured in such a way that heat from the laser devices cannot enter the conversion element. To this end, the mounting element 14 includes, for example, bridges separating the region of the mounting element of the below the conversion element 12 from regions below the laser devices. Similarly, the mounting element may be formed, at least in part, of a material having poor thermal conductivity. For example, this material may form the bridges between the regions below the conversion element below the laser devices. Thus, the mounting element 14 can be designed as a lead frame, for example.

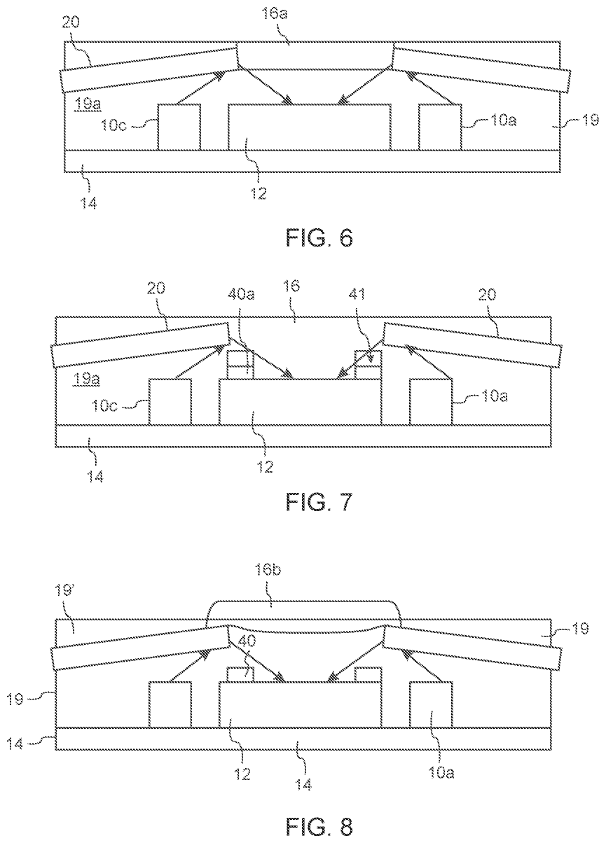

FIG. 6 shows an alternative embodiment of this lighting device in which, in contrast to the previous embodiment, the reflector elements are integrated within the housing. In addition, the reflector element 20 is designed as a hollow truncated pyramid. The opening of this truncated pyramid is arranged above the surface area 13 of the conversion element 12. Within the recess of the truncated pyramid forming the opening, a decoupling optic 16a made of a transparent material is provided. The housing 19 itself is filled with a transparent material 19a so that the reflector element and the outcoupling optics 16a are held in position

FIG. 3 shows a further design of a lighting device according to the proposed principle in its top view. A corresponding side view is shown in FIG. 8. The lighting device is constructed in a similar manner to the embodiments of FIG. 1. However, it additionally comprises a ring 40 on the conversion element 12. This ring is arranged in an elliptical or circular shape around the surface area 13 and forms a circumferential ring. In some embodiments, the ring has substantially perpendicular sidewalls with respect to the surfaces of the regions 13. In other embodiments, these sidewalls may also be inclined so that light emitted from the surface regions 13 is reflected off the sidewalls and emitted toward the emission region 16.

Furthermore, it can be seen in the side view of FIG. 8 of this embodiment that the reflector elements 20 are arranged inclined within the housing. The inclination is such that the ducks of the reflector element adjacent to the housing sides are closer to the mounting element. The angle thus created between the surface emitting region of the laser devices 10a and 10c and the reflector element 20 results in a shallower angle of incidence and thus a slightly different reflection of the pump light emitted by the laser devices.

By a suitable choice of the height of the ring 40 as well as the inclination and the position of the reflector elements 20 above the laser devices 10a and 10c and the position of the conversion element 12, a suitable light guidance into the center of the conversion element 12 can be achieved. Within the area 13 of the conversion element 12, a conversion of the light takes place so that a white mixed light is obtained. This is emitted upwardly from the conversion element 12 toward an outcoupling optic 16b. The outcoupling optics 16b is integrated in the cover of the housing 19 as a lens for light shaping and partially overlaps the reflector elements 20 integrated in the housing.

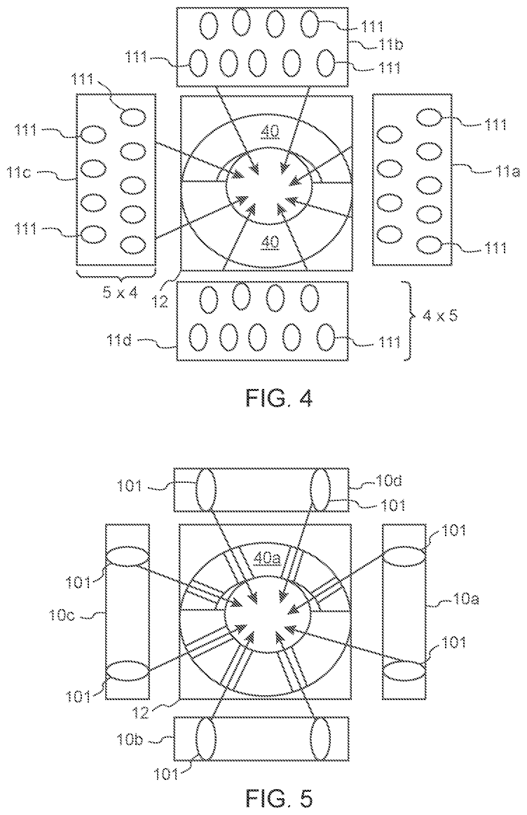

FIG. 4 shows a further embodiment in plan view, in which the laser devices are designed as vertical emitting laser diodes. These so-called VCSELs are characterized by a particularly small design, so that the laser devices shown in embodiments are constructed by an array of 4×5 individual VCSELs. As a result, each laser device 11a to 11d has a total of nine surface emitting regions. Two opposing laser devices each are arranged in the same orientation on the mounting member. In other words, in this 5×4 VCSEL array in the laser device, one strip with four surface emitting regions and one strip with five surface emitting regions of VCSELs are adjacent to each two opposite edges of the conversion element 12.

Each VCSEL of the laser devices 11a to 11d has an optical system integrated in or applied to the surface emitting area, which is designed to direct the pump light generated by the VCSEL onto the reflector elements. FIG. 8 shows a corresponding side view of these reflector elements, except that, in contrast to the laser devices 10a and 10c, the matrices from the VCSELs are now inserted.

FIG. 5 is a further design of a lighting device according to the proposed principle in plan view. FIG. 7 is a corresponding embodiment in side view. As can be seen in the side view of FIG. 7, the ring 40a enclosing the surface area 13 of the conversion element 12 is made significantly higher. This serves, on the one hand, to block stray light from the laser devices from the outside and, on the other hand, to reflect the light converted by the conversion element 12 of one of its internal conversions and to radiate it into the output region 16. The ring includes, as shown in the top view, a plurality of recesses 41 located at the position of the light cones or light beams emitted by the laser devices 10a to 10d. Thus, the recesses 41 in the ring 40a allow the pump light generated by the laser devices 10a to 10d to pass through and otherwise prevent stray light from impinging on the region 13 of the conversion element. In this embodiment example, the reflector element 20 is also designed as a circumferential ring whose underside is inclined as in the previous embodiment examples.

FIGS. 9 to 12 show different embodiments of an HCSEL or VCSEL, as applicable in the laser devices of the proposed lighting device. FIG. 9 shows a surface emitting laser whose two emitting regions 101 are driven by the same laser module. Here, the laser device comprises a GaN substrate 111 on which an anti-reflection layer 110 is deposited. An n-contact 119 is applied between the two surface emitting regions 101. This serves to supply the charge carriers. On the side of the GaN layer 111 facing away from the contact, a DBR structure 112 is connected. Downstream of the DBR structure 112 is an n-doped GaN layer 116 and a multiple quantum well 115. The multiple quantum well 115 is in turn connected to the p-contact 114 via a p-doped layer 117.

To create an HCSEL, the side regions are now subjected to an etching process so that inclined facets 113 are formed, in particular facets that are beveled or inclined at a 45° angle. The HCSEL thus has a 45 degree etched facet that creates a total internal reflection within the structure 115 acting as a laser resonator. The laser light exits the cavity at an angle perpendicular to the substrate. In some aspects, the facet may further be covered with a reflective yet electrically insulated layer.

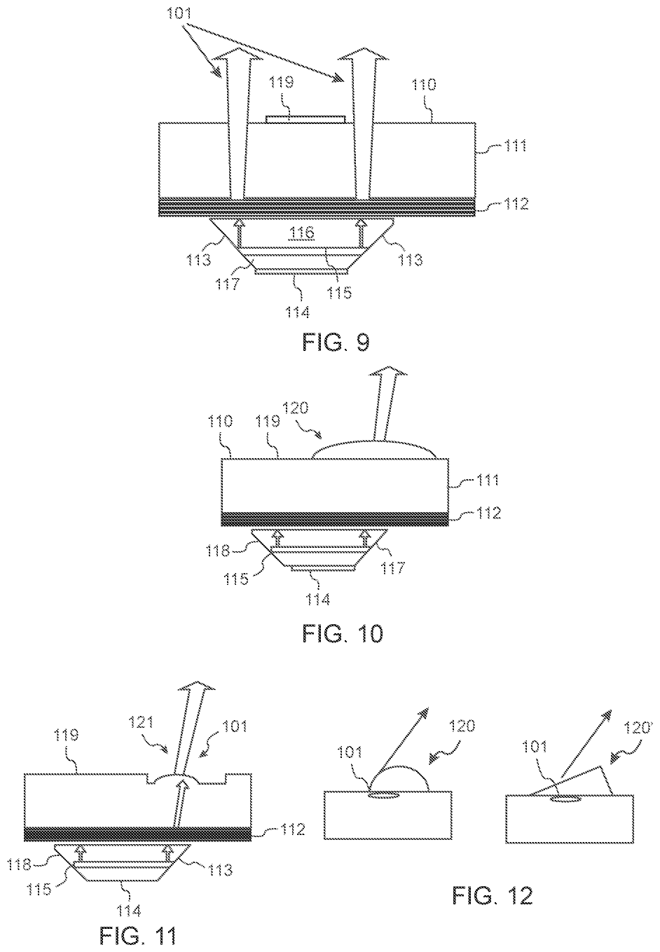

FIG. 10 shows a similar configuration as in FIG. 9, the main difference being that here only one facet is provided with a reflective layer 113 suitable for total reflection. Above this layer, a lens 120 is applied to the GaN substrate 111 above the laser facet 113. This serves to direct the totally reflected laser light passing through the DBR structure in the desired direction onto the conversion element. An alternative embodiment of an HCSEL laser is shown in FIG. 11. In this laser, a corresponding optic 121 is provided within and integrated into the GaN layer 111. In addition, the anti-reflection layer 110 is arranged above the decoupling optics 121. This design has the advantage that it can be integrated into the HCSEL laser during the manufacturing phase and adjusted to the underlying structure and the position of the facet.

Corresponding designs are also available for the VCSEL laser. Like the HCSEL, this forms a surface-emitting component, but here the resonator is arranged vertically and not horizontally. FIG. 12 shows two designs of a VCSEL, in which different optical elements 120 are applied to the surface emitting region. On the one hand, these can form a lens, as shown for example in the left partial figure, but on the other hand they can also form a prism structure, as shown in the right partial figure. Both optics 120 serve to direct the pump light emitted by the laser device in the direction of the reflector element for subsequent suitable reflection onto the conversion element.

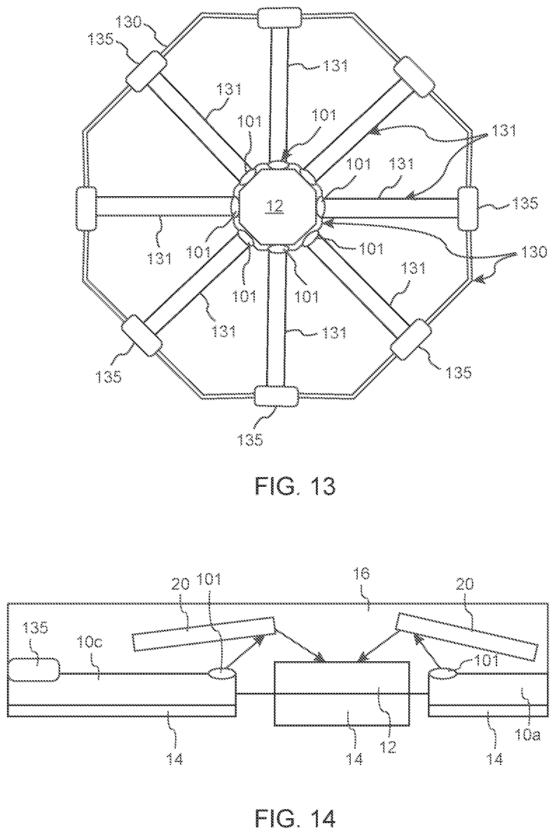

In addition to the embodiments shown here, there are further possibilities for arranging the respective laser devices in relation to the conversion element 12, whereby various further aspects such as the heat generation of the laser devices, the size of the lighting device and the desired light emission ratios can be taken into account. FIG. 13 shows a further embodiment in its top view. In FIG. 14, the embodiment of the lighting device is shown schematically in side view.

In the illustrated embodiment, the lighting device is designed with several laser devices arranged between the sides of two trenches 130. The two opposing trenches 130 thereby form an octahedron, with the laser resonators 131 of the respective laser devices located between the side edges of the trenches. On each side of the trench 130 facing away from the conversion element 12, a highly reflective layer 135 is arranged to direct the light generated by the laser device back toward the output facet and thus the surface emitting region 101. In this regard, the outer trench may have a vertical wall covered with the layer 135. a control diode or other element for controlling the laser device may also be arranged at this location.

The trench 130 adjacent to the conversion element includes an etched 45° facet on each of its sidewalls, which is perpendicular to the respective laser resonator. Due to this embodiment, at least large areas of the elongated laser resonator are located further away from the conversion element 12, so that the heat generated during operation can influence the conversion element 12 even less. Only the surface emitting regions of the respective laser devices are located close to the conversion element 12. This provides an even better thermal separation between the conversion element and the individual laser devices, since a heat is mainly generated in the laser resonator which is now located further away.

In addition, this arrangement allows the laser resonator to be designed more flexibly in terms of its length because, in contrast to the previous embodiment examples, it is not restricted by the side length of the conversion element. In this way, laser resonators are possible which comprise a particularly high quantum efficiency, photon multiplication and thus luminosity. The conversion element as well as the two trenches 130, between which the laser devices with their combs are arranged, are designed in the form of an octahedron in this embodiment example. Thus, the lighting device comprises a total of 8 laser devices whose surface-emitting areas are adjacent to the conversion element. Through the inclined reflector element 12 shown in FIG. 14, which extends partially above the laser resonators and over the edge region of the conversion element 12, the pump light emitted in the surface emitting region 101 is reflected onto the conversion element. As in the preceding examples, the surface emitting regions include integrated or attached optics to emit the light beam as shown not perpendicular to the surface or laser resonator, but already in the direction of the conversion element.

The conversion element 12 now generates a yellow component with part of the incident pump light, which is mixed with the remaining pump light to form a white mixed light. Unconverted pump light is reflected back by the conversion element and thus enters the radiation area 16 together with the converted light and is emitted as white mixed light.

The side view of FIG. 14 also shows the mounting element 14. This is designed as a lead frame and comprises first elements 14 on which the laser devices 10a and 10c are arranged. In addition, the mounting element comprises a central area 14′ which, as shown, is spatially and thus also thermally separated from the elements 14. The conversion element 12 is now arranged on the central area 14. The central area 14 is connected to the elements 14 only via thin bridges, which are not shown here. In this way, very good thermal separation is achieved between the individual laser devices and the conversion element. Alternatively, the central area 14′ can also be connected to the areas 14 via a plastic, for example a mold. Such a plastic is generally characterized by low thermal conductivity, so that thermal separation is thereby achieved or improved.

Additionally, it should be noted that due to the arrangement of the laser devices, an average heat contribution also occurs spatially further away from the conversion element 12, so that thermal coupling and transfer of this heat to the conversion element 12 is further reduced. Overall, this embodiment can thus be operated at a very high illumination intensity to provide an illumination unit with a high light intensity.

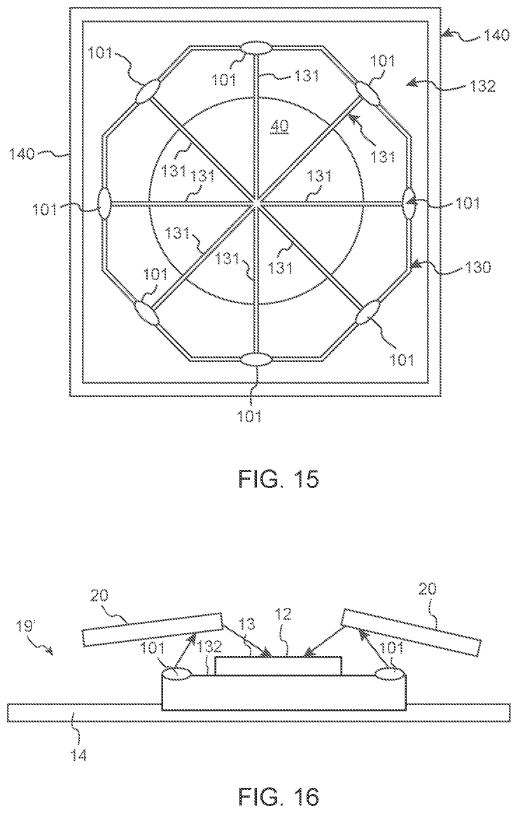

FIGS. 15 and 16 show another example of a lighting device, in which the lighting device is characterized by a particularly compact design combined with high luminosity. As shown, the lighting device is surrounded by a mesa edge 140 and has an essentially square design. The individual components can then be separated and further processed along the existing mesa edge.

Centrally located on the surface of this structure is the conversion device 12, as shown in FIG. 16. Next to this, as in the previous example, a trench 130 is provided, which is designed as an octahedron and surrounds the conversion element. This is formed here as a ring or cylinder, but can also comprise an octahedron-shaped structure or another shape. The trench has side walls that are etched at a 45° angle. As a result, the sidewalls form an element for total reflection of a light generated in the laser resonator, so that light is emitted upwards, resulting in a surface emitting region 101 for the laser devices.

In this embodiment, the laser resonators 131 of the corresponding laser devices are located below the conversion element 12 meet centrally at a point. In other words, one laser resonator each is thus implemented with two corresponding surface emitting regions 101.

In this embodiment, the conversion element is arranged on a common in contact 132. The common n-contact comprises a continuous metallic surface on which heat can be transported away in a suitable manner. The respective laser resonators can be contacted individually on the rear side via a p-contact.

In this embodiment, a particularly compact realization is thus achievable. Nevertheless, a thermal separation between the conversion element and the underlying laser devices remains largely present due to the metallic surface 132, which also acts as a heat conductor. By means of suitable outcoupling optics in the surface-emitting region 101, the light generated by the laser devices is emitted onto the inclined reflector elements 20 and reflected by them onto the conversion element 12.

The individual elements of the examples and embodiments presented here can be combined without further ado. In particular, the mounting element with its two elements thermally separated from each other can be used for the lighting devices. The same applies to the reflector elements 20 and decoupling structures 16, whose individual examples can also be used for other examples in the respective embodiments.

1. A lighting device, comprising:
a housing with a light emission area and a mounting element arranged below the light emission area;
a conversion element arranged on the mounting element,
wherein the conversion element is adapted to convert pump light of one wavelength incident on the conversion element in a surface region into a radiation light of a second wavelength and to radiate it over the surface region which lies below the light emission region;
a first and a second surface emitting laser device for generating the pump light, which are arranged on the mounting area laterally offset from the light emitting area;
wherein the first laser device is disposed along and spaced from a first side of the conversion element, and the second laser device is disposed along and spaced from a second side of the conversion element opposite the first side;
a reflector element connected to the housing and disposed above the first and second laser devices and configured to reflect the pump light emitted by the laser devices onto the surface area;
wherein the mounting element is configured to dissipate heat generated during operation of the first and second laser devices while at the same time substantially thermally decoupling from the conversion element; and
wherein the first and/or second surface emitting laser device comprises a light-shaping optic arranged on or integrated in the respective surface-emitting region, so that an emission of the pump light occurs at an angle tilted with respect to the perpendicular, in particular in the direction of the conversion element.

2. The lighting device according to claim 1, further comprising third and fourth laser devices disposed opposite each other and spaced from the conversion element such that the laser devices are optionally disposed along or on the sides of a notional rectangle about the conversion element.

3. The lighting device according to claim 1, wherein the first and/or second laser devices comprise at least one HCSEL or one VCSEL.

4. The lighting device according to claim 3, wherein a surface emitting region of the HCSEL or the VCSEL is parallel to the surface region of the conversion element.

5-6. canceled

7. The lighting device according to claim 1, wherein the laser devices are arranged parallel to the conversion element.

8. The lighting device according to claim 1, wherein the laser device comprises a laser resonator substantially perpendicular to the side of the conversion element adjacent to the laser device, the surface emitting region of the laser device being adjacent to the conversion element.

9. The lighting device of claim 8, wherein a highly reflective region of the laser cavity faces away from the conversion element.

10. The lighting device of aclaim 1, wherein the laser device comprises a laser resonator extending below the conversion element, the surface emitting region of the laser device being adjacent the conversion element.

11. The lighting device according to claim 8, wherein the surface emitting region is formed by an etched facet, in particular with an angle of 25° to 65°, in particular of 40° to 50°.

12. The lighting device according to claim 1, wherein the housing is at least partially filled with a transparent material.

13. The lighting device according to claim 1, wherein a reflective surface of the reflector element is aligned parallel to the surface portion of the conversion element.

14. The lighting device according to claim 1, in which the reflector element is formed as a ring, the inner recess of which forms the light emission area.

15. The lighting device according to claim 13, wherein the reflector element is formed as a truncated cone; and/or the reflective surface of the reflector element is inclined with respect to the surface area of the conversion element.

16. The lighting device according to claim 1, wherein at least one surface of the reflector element comprises a metal, in particular silver or aluminum.

17. The lighting device according to claim 1, further comprising an outcoupling structure, in particular a light-guiding or light-shaping optical system, arranged in or on the light-emitting region.

18. The lighting device according to claim 1, wherein the reflector element is disposed on the housing.

19. The lighting device according to claim 1, further comprising a member surrounding the surface portion of the conversion member and extending over the surface portion toward the light emitting portion.

20. The lighting device of claim 19, wherein the member surrounding the surface portion of the conversion member is provided with recesses for the pump laser light of the laser devices.

21. The lighting device according to claim 19, wherein the surrounding element comprises a reflective surface and/or inclined surface adjoining the surface area.

22. The lighting device according to claim 1, wherein an inwardly directed outer surface of the conversion element is of reflective design.

23. The lighting device of claim 21, wherein the surrounding element and/or the inwardly facing outer surface is formed with TiO2.
